(19) United States
(12) Patent Application Publication
(10) Pub. No.: US 2023/0282767 A1
(43) Pub. Date: Sep. 7, 2023

(54) MICRO LED, MICRO LED PANEL AND MICRO LED CHIP

(71) Applicant: JADE BIRD DISPLAY (SHANGHAI) LIMITED, Shanghai (CN)

(72) Inventors: Jian GUO, Shanghai (CN); Qiming LI, Shanghai (CN); Huiwen XU, Shanghai (CN)

(21) Appl. No.: 18/116,395

(22) Filed: Mar. 2, 2023

(30) Foreign Application Priority Data
Mar. 3, 2022 (WO) PCT/CN2022/079059

(51) Int. Cl. H01L 33/10; H01L 33/62; H01L 33/24; H01L 33/52

(52) U.S. Cl. CPC H01L 33/10; H01L 33/62; H01L 33/24; H01L 33/52

(57) ABSTRACT

A micro LED includes a light emitting structure; an electrical conductive layer formed on the light emitting structure; and a reflective layer formed on the electrical conductive layer, wherein a top surface of the reflective layer is lower than a top surface of the electrical conductive layer.

### CROSS-REFERENCE TO RELATED APPLICATIONS

The disclosure claims the benefits of priority to PCT Application No. PCT/CN2022/079059, filed on Mar. 3, 2022, which is incorporated herein by reference in its entirety.

### TECHNICAL FIELD

The present disclosure generally relates to light emitting diode technology field, and more particularly, to a micro light emitting diode (LED), a micro LED panel, and a micro LED chip.

### BACKGROUND

Inorganic micro pixel light emitting diodes, also referred to as micro light emitting diodes, micro LEDs or μ-LEDs, become more and more important since they are used in various areas including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, fast response rate, larger work temperature range, higher resolution, wider color gamut, higher contrast, lower power consumption, and operability at higher current density.

Conventionally, the inorganic micro LEDs are manufactured by etching III-V group epitaxial layers to form multiple mesas. Most of the light emitting from a sidewall of the mesa has a large emitting angle that is orthogonal to the micro display. However, in an augmented reality (AR) device, emitted light with a large emitting angle is blocked and lost so that the emitting light cannot reach a user's eyes. As a result, the light emitting efficiency is reduced. Thus, there is a need to reduce the loss of the emitting light from the sidewalls of the mesas.

The above discussion is only provided to assist in understanding the technical solutions of the present disclosure, and does not constitute an admission that the above is prior art.

### SUMMARY OF THE DISCLOSURE

The present disclosure provides an improved micro LED not subject to the aforementioned problems and disadvantages.

Embodiments of present disclosure provide a micro LED. The micro LED includes a light emitting structure; an electrical conductive layer formed on the light emitting structure; and a reflective layer formed on the electrical conductive layer, wherein a top surface of the reflective layer is lower than a top surface of the electrical conductive layer.

Embodiments of the present disclosure also provide a micro LED panel. The micro LED panel includes one or more above described micro LEDs, wherein the reflective layer is formed between adjacent ones of light emitting structures of the two or more micro LEDs.

Embodiments of the present disclosure also provide a micro LED chip. The micro LED chip includes one or more above described micro LED panels.

Additional advantages and features of the present disclosure will be further understood by the following detailed descriptions and the appended drawings.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 is a structural diagram of an exemplary micro LED according to some embodiments of the present disclosure.

FIG. 2 is a structural diagram of an exemplary micro LED panel according to some embodiments of the present disclosure.

FIG. 3 is a structural diagram illustrating adjacent micro LEDs according to some embodiments of the present disclosure.

FIG. 4 is a structural diagram of an exemplary micro LED chip according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

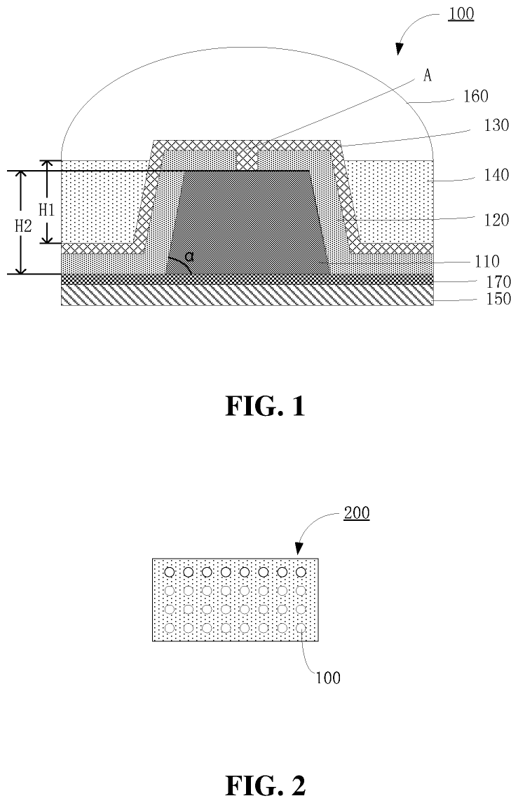

FIG. 1 is a structural diagram of an exemplary micro LED100 according to some embodiments of the present disclosure. Referring to FIG. 1, the micro LED100 includes a light emitting structure 110, a passivation layer 120, an electrical conductive layer 130, a reflective layer 140, and a conductive substrate 150.

The light emitting structure 110 is formed on the conductive substrate 150. In some embodiments, the light emitting structure 110 includes a PN junction and a quantum well. For example, the light emitting structure 110 includes a PN junction formed by an n-doped semiconductor layer and a p-doped semiconductor layer. The quantum well is formed between the n-doped semiconductor layer and the p-doped semiconductor layer. The light emitting structure 110 is a mesa structure with a flat top surface. In some embodiments, the light emitting structure 110 is a cone structure without a steeple top. The conductive substrate 150 is a circuit substrate, such as an IC (integrated circuit) substrate. The light emitting structure 110 is bonded on the conductive substrate 150 via a metal bonding process. A metal bonding layer 170 is formed between the light emitting structure 110 and the conductive substrate 150. The material of the metal bonding layer 170 can comprise one or more reflective metal materials so as to reflect light from the bottom of the light emitting structure 110 to the top of the light emitting structure 110. With the metal bonding layer 170, there is substantially no emitting light lost from the bottom and light emitting efficiency is improved.

The light emitting structure 110 is covered by the passivation layer 120 with an exposed area A on the top. That is, the passivation layer 120 is formed on the top and sidewall of the light emitting structure 110 except for the exposed area A. The passivation layer 120 is also formed over the conductive substrate 150. In this embodiment, as shown in FIG. 1, the passivation layer 120 is further formed on the surface of the metal bonding layer 170. The material of the passivation layer 120 can be a dielectric material. In some embodiments, the material of the passivation layer 120 is selected from SiO2, Si3N4, etc. The electrical conductive layer 130 is formed on the passivation layer 120, and fills the exposed area A. Therefore, a connected hole is formed. The material of the electrical conductive layer 130 can be a transparent conductive material. In some embodiments, the material of the electrical conductive layer 130 is selected from ITO(IN) (tin-doped indium oxide), FTO (Fluorine-doped tin oxide), etc.

The reflective layer 140 is formed on the electrical conductive layer 130. A top surface of the reflective layer 140 is higher than a top surface of the light emitting structure 110 and lower than a top surface of the electrical conductive layer 130. In some embodiments, a top surface of the passivation layer 120 is higher than the top surface of the reflective layer 140. In some embodiments, the material of the reflective layer 140 can be metal or oxide material. In some embodiments, the reflective layer 140 is formed by stacked layers. In some embodiments, the reflective layer 140 is stacked by Ni, Ag, or Au layers. In some embodiments, the thickness of the reflective layer 140 is greater than half thickness of the light emitting structure 110, e.g., H1>½H2, where H1 and H2 are the thicknesses shown in FIG. 1.

The micro LED100 further includes a micro lens 160 on the electrical conductive layer 130. The micro lens 160 covers the top surface of the electrical conductive layer 130 and parts of the top surface of the reflective layer 140, that is, a bottom surface of the micro lens 160 is greater than a top surface of the electrical conductive layer 130. The material of the micro lens 160 is selected from silicon oxide, photo resist, etc.

As shown in FIG. 1, in some embodiments, an inclined angle a of the sidewall of the light emitting structure 110 is less than 90°. In some embodiments, the inclined angle a of the sidewall of the light emitting structure 110 is less than 90° and greater than 60°. The top surface of the electrical conductive layer 130 is higher than the top surface of the reflective layer 140.

The micro LED 100 provided in the present disclosure improves efficiency of light emitting at a small angle via the reflective layer 140. The light emitting from the sidewall of the light emitting structure 110 is initially reflected one or more times by the reflective layer 140, and emitted from the top surface of the light emitting structure 110. Therefore, the loss of the light emitting from the sidewall is reduced, and the light emitting efficiency from the top surface of the light emitting structure 110 is improved. As a result, substantially all the light can be emitted out of the top surface of the light emitting structure 110 without being blocked in devices (e.g., AR devices).

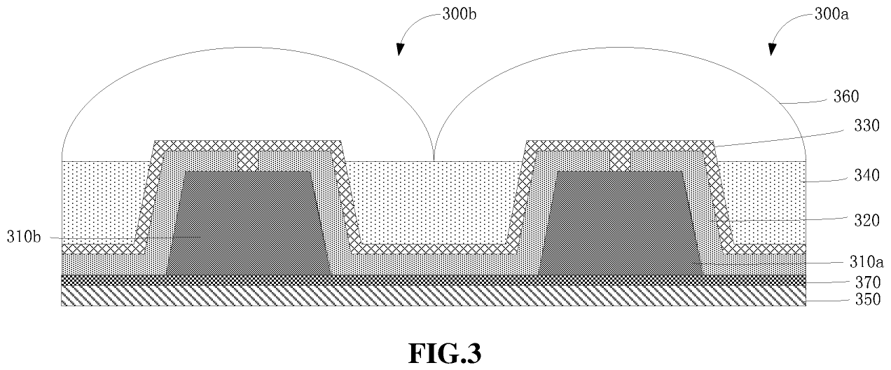

FIG. 2 is a structural diagram showing a plan view of an exemplary micro LED panel 200 according to some embodiments of the present disclosure. As shown in FIG. 2, the micro LED panel 200 includes one or more of the above-described micro LEDs100. The one or more micro LEDs100 are arranged in an array on the micro LED panel 200. FIG. 3 is a structural diagram showing in a side sectional view of the micro LEDs 100, as exemplary adjacent micro LEDs 300a and 300b included in the micro LED panel 200, according to some embodiments of the present disclosure. Referring to FIG. 2 and FIG. 3, an electrical conductive layer 330 is formed on and covers the whole micro LED panel 200. A reflective layer 340 is formed between adjacent light emitting structures 310a and 310b respectively of the micro LEDs 300a and 300b, and covers the whole micro LED panel 200. The structure of reflective layer 340 is a net with an array of holes respectively corresponding to the array of micro LEDs 100 on the micro LED panel 200.

In some embodiments, in the micro LED panel 200, the micro LEDs 100 array can be 640*480, 1280*720 or 1920*1080, etc.

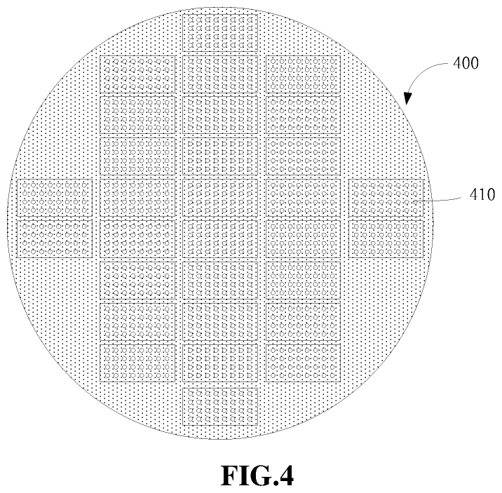

FIG. 4 is a structural diagram showing a plan view of an exemplary micro LED chip 400 according to some embodiments of the present disclosure. As shown in FIG. 4, the micro LED chip 400 includes one or more micro LED display panels 410 each having a structure of the micro LED panel described above with reference to FIGS. 2 and 3. Referring to FIG. 3 and FIG. 4, the electrical conductive layer 330 is formed on and covers the whole micro LED chip 400. The reflective layer 340 is formed between the adjacent light emitting structures 310a and 310b, and covers the whole micro LED chip 400. The structure of the reflective layer 340 can be a net with an array of holes respectively corresponding to the micro LEDs 100.

It is noted that the number of micro LEDs100 in the micro LED panel 200 in FIG. 2, and the number of micro LED panels 410 shown in FIG. 4 are only for illustrative purpose. The number of micro LEDs in a micro LED panel and the number of micro LED panels in a micro LED chip can be varied in practice.

The embodiments may further be described using the following clauses:
1. A micro Light Emitting Diode (LED), comprising:
a light emitting structure;
an electrical conductive layer formed on the light emitting structure; and
a reflective layer formed on a portion of the electrical conductive layer, wherein a top surface of the reflective layer is lower than a top surface of the electrical conductive layer.
2. The micro LED according to clause 1, wherein the top surface of the reflective layer is higher than a top surface of the light emitting structure.
3. The micro LED according to clause 1 or 2, further comprising a passivation layer formed between the light emitting structure and the electrical conductive layer.
4. The micro LED according to clause 3, wherein a top surface of the passivation layer is higher than the top surface of the reflective layer.
5. The micro LED according to any one of clauses 1 to 4, wherein a material of the reflective layer is metal or oxide material.
6. The micro LED according to any one of clauses 1 to 5, wherein the reflective layer is formed by stacked layers.
7. The micro LED according to clause 6, wherein the reflective layer comprises stacked layers of Ni, Ag, or Au.
8. The micro LED according to any one of clauses 1 to 7, wherein an inclined angle of a sidewall of the light emitting structure is less than 90°.
9. The micro LED according to any one of clauses 1 to 8, wherein a thickness of the reflective layer is larger than half a thickness of the light emitting structure.
10. The micro LED according to any one of clauses 1 to 9, wherein the light emitting structure is a mesa structure with a flat top surface.
11. The micro LED according to clause 10, wherein the light emitting structure is a cone structure without a steeple top.
12. The micro LED according to any one of clauses 1 to 11, further comprising a micro lens formed on the electrically conductive layer and the reflective layer.
13. The micro LED according to any one of clauses 1 to 12, further comprising a conductive substrate electrically connected with the light emitting structure and formed under the light emitting structure.
14. The micro LED according to clause 13, wherein the conductive substrate is an integrated circuit (IC) substrate.
15. The micro LED according to clause 13, wherein the conductive substrate is bonded with the light emitting structure.
16. A micro LED panel comprising two or more micro LEDs according to any one of clauses 1 to 15, wherein the reflective layer is formed between adjacent ones of light emitting structures of the two or more micro LEDs.
17. A micro LED chip comprising one or more micro LED panels according to clause 16.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro Light Emitting Diode (LED), comprising:
a light emitting structure;
an electrical conductive layer formed on the light emitting structure; and
a reflective layer formed on a portion of the electrical conductive layer, wherein a top surface of the reflective layer is lower than a top surface of the electrical conductive layer.

2. The micro LED according to claim 1, wherein the top surface of the reflective layer is higher than a top surface of the light emitting structure.

3. The micro LED according to claim 1, further comprising a passivation layer formed between the light emitting structure and the electrical conductive layer.

4. The micro LED according to claim 3, wherein a top surface of the passivation layer is higher than the top surface of the reflective layer.

5. The micro LED according to claim 1, wherein a material of the reflective layer is metal or oxide material.

6. The micro LED according to claim 1, wherein the reflective layer is formed by stacked layers.

7. The micro LED according to claim 6, wherein the reflective layer comprises stacked layers of Ni, Ag, or Au.

8. The micro LED according to claim 1, wherein an inclined angle of a sidewall of the light emitting structure is less than 90°.

9. The micro LED according to claim 1, wherein a thickness of the reflective layer is larger than half a thickness of the light emitting structure.

10. The micro LED according to claim 1, wherein the light emitting structure is a mesa structure with a flat top surface.

11. The micro LED according to claim 10, wherein the light emitting structure is a cone structure without a steeple top.

12. The micro LED according to claim 1, further comprising a micro lens formed on the electrically conductive layer and the reflective layer.

13. The micro LED according to claim 1, further comprising a conductive substrate electrically connected with the light emitting structure and formed under the light emitting structure.

14. The micro LED according to claim 13, wherein the conductive substrate is an integrated circuit (IC) substrate.

15. The micro LED according to claim 13, wherein the conductive substrate is bonded with the light emitting structure.

16. A micro LED panel comprising two or more micro LEDs, wherein each one of the two or more micro LEDs comprises:
a light emitting structure;
an electrical conductive layer formed on the light emitting structure; and
a reflective layer formed on a portion of the electrical conductive layer, wherein a top surface of the reflective layer is lower than a top surface of the electrical conductive layer;
wherein the reflective layer is formed between adjacent ones of light emitting structures of the two or more micro LEDs.

17. A micro LED chip comprising one or more micro LED panels, wherein each one of the one or more micro LED panels comprises two or more micro LEDs, and each one of the two or more micro LEDs comprises:
a light emitting structure;
an electrical conductive layer formed on the light emitting structure; and
a reflective layer formed on a portion of the electrical conductive layer, wherein a top surface of the reflective layer is lower than a top surface of the electrical conductive layer;
wherein the reflective layer is formed between adjacent ones of light emitting structures of the two or more micro LEDs.
